(19) United States
(12) Patent Application Publication
(10) Pub. No.: US 2025/0273481 A1
(43) Pub. Date: Aug. 28, 2025

(54) METHOD OF MANUFACTURING SEMICONDUCTOR DEVICES AND CORRESPONDING DEVICE

(71) Applicant: STMicroelectronics International N.V., Geneva (CH)

(72) Inventors: Guendalina CATALANO, Milano (IT); Marco DEL SARTO, Monza (IT); Thomas GOTTARDI, Agrate Brianza (MB) (IT)

(73) Assignee: STMicroelectronics International N.V., Geneva (CH)

(21) Appl. No.: 19/057,264

(22) Filed: Feb. 19, 2025

(30) Foreign Application Priority Data
Feb. 28, 2024 (IT) 102024000004246

(51) Int. Cl. H01L 21/56; H01L 23/00; H01L 23/31

(52) U.S. Cl. CPC H01L 21/56; H01L 23/3107; H01L 24/40; H01L 2224/40245

(57) ABSTRACT

An integrated circuit semiconductor chip is arranged on a substrate having electrically conductive leads and laser direct structuring (LDS) encapsulation material is molded onto the semiconductor chip. In response to LDS processing applied to the LDS encapsulation material molded onto the semiconductor chip, a pattern of electrically conductive formations is provided coupled to selected ones of the electrically conductive leads. Electrically conductive material is provided onto the pattern of electrically conductive formations and one or more planar electrically conductive clips are mounted onto the electrically conductive material. The clip or clips is/are electrically coupled via the electrically conductive material to selected ones of the electrically conductive leads. Further encapsulation material can be molded onto the electrically conductive clip or clips.

PRIORITY CLAIM

This application claims the priority benefit of Italian Application for Patent No. 102024000004246 filed on Feb. 28, 2024 xf, the content of which is hereby incorporated by reference in its entirety to the maximum extent allowable by law.

### TECHNICAL FIELD

The description relates to manufacturing semiconductor devices.

Solutions as described herein can be applied to power (integrated circuit—IC) semiconductor devices, for automotive products, for instance.

### BACKGROUND

In power integrated circuit (IC) semiconductor devices, the current transferred from a high-power section to output pads of the device can be significant.

Ribbons or clips can be used in the place of wires for current transfer to output.

Providing electrical coupling of a power section of an (integrated circuit) semiconductor device and outer pins or pads using electrically conductive ribbons involves bonding ribbons via ultrasonic wedge-bonding. Such a bonding method may undesirably damage the leadframe (at the relatively small outer pads, for instance).

When a substrate is intended to be used that is expected to be unable to sustain the stress induced by ultrasonic ribbon welding process, clips are used instead of ribbons: clips are connected on both die and lead using solder paste or glue, with no substantial stress applied.

Clips are currently stamped starting from laminar material. Pins with the purpose of centering a clip on a leadframe can be created in the clip material by punching. Recesses can be created at corresponding leadframe positions to house the clip pins for centering purposes.

In small packages (power Quad-Flat No Leads (QFN) packages, for instance) and/or if the final package includes several channels, more pads are needed and the dimensions for recesses on leadframe and clips may become relatively small. These relatively small dimensions may lead to difficulties in clips manufacturing and handling.

United States Patent Application Publication No. 2022/0102254 A1 (incorporated herein by reference) discloses a chip package for power modules including at least one semiconductor die; a driver circuit for controlling the at least one semiconductor die; a protective layer formed on a die active surface of the at least one die and a driver active surface of the driver circuit; a metal unit having at least one metal feature; and a molding layer for encapsulating the at least one semiconductor die, the driver circuit, the protective layer and metal unit. The chip package is connected with an external circuit via the at least one metal feature.

Other references of interest include United States Patent Application Publication Nos. 2023/0253395 A1, 2019/0080989 A1 and 2012/0168922 A1 (all of which are incorporated herein by reference).

To summarize: if high currents are transferred from a die to the outer pads in an (integrated circuit—IC) semiconductor device, ribbons or clips represent advantageous alternatives to wires for electrically connecting these parts in the device. Ribbons are advantageous in so far as they can be easily shaped and directly welded to both a die and a leadframe using ultrasonic welding technology. For instance, aluminum or copper ribbons are welded on both die and leadframe using ultrasonic bonding. In some circumstances, the leadframes may not be strong enough to withstand the ultrasonic welding process. Bent/broken leadframes can be observed after a ribbon bonding step. Clips are placed in the proper position through a pick and place step. Clip bonding is performed using solder paste or glue as interface material between the clip itself and the die/lead. Solutions based on clips have to deal with various issues, like clip precise placement, possible movement during leadframe handling and cost: clip manufacturing and assembly cost can be a substantial fraction of package cost.

United States Patent Application Publication No. 2021/0183748 A1 (incorporated herein by reference) discloses a System in Package (SiP) semiconductor device that includes a substrate of laser direct structuring (LDS) material. First and second semiconductor dice are arranged at a first and a second leadframe structure at opposite surfaces of the substrate of LDS material. Package LDS material is molded onto the second surface of the substrate of LDS material. The first semiconductor die and the package LDS material lie on opposite sides of the substrate of LDS material. A set of electrical contact formations are at a surface of the package molding material opposite the substrate of LDS material. The leadframe structures include laser beam processed LDS material. The substrate of LDS material and the package LDS material include laser beam processed LDS material forming at least one electrically-conductive via providing at least a portion of an electrically-conductive line between the first semiconductor die and an electrical contact formation at the surface of the package molding material opposite the substrate.

Clip integration in an LDS process flow (also referred to as LDW, DCI or LISIPACK™) has been proposed in United States Patent Application Publication No. 2020/0203264 A1 (corresponding to U.S. Pat. No. 11,145,582 B2—incorporated by reference). This solution still requires a standard (bent) clip that might be hard to manufacture/mount, in particular in miniaturized power devices. The clip size area may be limited by the need to connect the clip to the leadframe at a bent portion.

There is a need in the art to contribute in addressing the issues above.

### SUMMARY

One or more embodiments relate to a method.

One or more embodiments relate to a corresponding (integrated circuit—IC) semiconductor device.

Solutions as described herein are compatible with known process steps in LDS (LDW, DCI or LISIPACK™) technology or panel level package (PLP) technology.

In a solution as described herein, an LDS-based die-to-leadframe interconnection (laser printed with metallized through-mold-vias (TMVs) and metal traces) may comprise additional TMVs to electrically and thermally connect a metal plate configured to receive a clip mounted thereon to a lead. An insulating film such as an Ajinomoto Build-up Film (ABF) can be laminated over the structure (alternatively, a further layer of LDS molding compound can be formed over the structure) and vias are opened in this additional insulating layer and filled with a solder paste. Then a flat clip is mounted, which can extend over some TMVs, increasing the available area.

Such a solution can also be implemented in the context of a panel level package (PLP) integration.

In various embodiments, an ABF film can be omitted, and the flat clip can be directly mounted on an LDS-printed metal plate with solder paste or glue.

To summarize, in various solutions as described herein: in the context of LDS (LDW, DCI or LISIPACK™) die-to-lead interconnection, a conductive layer (a metal plate, for instance) can be formed configured to receive a clip mounted thereon together with vias to connect the metal plate to the die and to at least one lead; an insulating film (ABF, for instance) can then be laminated with vias formed therein to be filled with solder paste; and a flat clip is mounted thereon which can extend over further die-to-lead connections that are electrically insulated from the clip.

### BRIEF DESCRIPTION OF THE DRAWINGS

One or more embodiments will now be described, by way of example only, with reference to the annexed figures, wherein:

FIGS. 1A to 1F are exemplary of a first possible sequence of steps in a process of manufacturing an (integrated circuit (IC)) semiconductor device;

FIGS. 2A to 2F are exemplary of another possible sequence of steps in a process of manufacturing an IC semiconductor device;

FIGS. 3A and 3B are a first example of possible steps in completing the sequence of steps of FIG. 2A to 2F;

FIGS. 4A and 4B are a second example of possible steps in completing the sequence of steps of FIG. 2A to 2F; and

FIGS. 5A, 5B, and 5C are perspective views (partly sectioned in the case of FIGS. 5A and 5B) that highlight possible features of IC semiconductor devices as discussed herein.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale. The edges of features drawn in the figures do not necessarily indicate the termination of the extent of the feature.

In the ensuing description, various specific details are illustrated in order to provide an in-depth understanding of various examples of embodiments according to the description. The embodiments may be obtained without one or more of the specific details, or with other methods, components, materials, etc. In other cases, known structures, materials, or operations are not illustrated or described in detail so that various aspects of the embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment”, “in one embodiment”, or the like, that may be present in various points of the present description do not necessarily refer exactly to one and the same embodiment. Furthermore, particular configurations, structures, or characteristics may be combined in any adequate way in one or more embodiments.

The headings/references used herein are provided merely for convenience and hence do not define the extent of protection or the scope of the embodiments.

The meaning of various terms or designations that may be used or may be referred to in this description will now be briefly recalled. This is primarily by way of immediate reference, being otherwise understood that these terms or designations are well known to those of skill in the art of manufacturing (integrated circuit, IC) semiconductor devices.

Package: this is a case that surrounds the circuit material to protect it from corrosion or physical damage and allow mounting of the electrical contacts connecting it to a printed circuit board.

Additive manufacturing (oftentimes referred to also as 3D printing): this designation denotes processes for the construction of a three-dimensional object from a CAD model or a digital 3D model.

Ajinomoto Build-up Film (or ABF): this is an example of an insulating layer suited for use in protecting semiconductor chips or dice (these terms are used herein as synonymous) while also ensuring electrical connectivity so that different components of a chip can be attached to one other. ABF is now available from various sources such as Ibiden, Shinko, Unimicron and AT&S.

Laser Direct Structuring (LDS): this is a combination of laser patterning and plating processes to create electrical interconnections obtained via laser “writing” (hence the possible designation of Laser Direct Writing (LDW)); LDS facilitates device interconnection with a substrate via metal—for instance copper: hence the possible designation Direct Copper Interconnect (DCI)—directly grown with additive processes.

Laser Direct Structuring (LDS, LDW, DCI) is a technology based on the structuring (writing) of a plastic material by a laser source. The lasered traces are then plated in order to provide a conductive patterning.

Laser Induced Strip Interconnection (LISI) is another designation sometimes applied to that technology. In the LISIPACK™ family of ST products an LDS molding compound is used to cover (encapsulate) a die and electrically conductive lines (vias, traces) are “structured” in the LDS molding compound.

As discussed in the introductory portion of this description, LDS is a technology based on the structuring of a plastic material by a laser source.

LDS is now used in various sectors of the industrial and consumer electronics markets, for instance for high-performance antenna integration, where an antenna design can be directly formed onto a molded plastic part.

In an exemplary process, the molded parts can be produced with commercially available insulating resins that include additives suitable for the LDS process; a broad range of resins such as polymer resins like PC, PC/ABS, ABS, LCP and LDS additives such as copper-based, copper-chromite seed-forming additives are currently available for that purpose.

A laser beam can be used to transfer (“structure” or “activate”) a desired electrically conductive pattern onto an LDS molding compound that may then be subjected to metallization to finalize a desired conductive pattern.

Metallization may involve electroless plating followed by electrolytic plating. Electroless plating, also known as chemical plating, is a class of industrial chemical processes that creates metal coatings on various materials by autocatalytic chemical reduction of metal cations in a liquid bath. In electrolytic plating, an electric field between an anode and a workpiece, acting as a cathode, forces positively charged metal ions to move to the cathode where they give up their charge and deposit themselves as metal on the surface of the workpiece.

LDS can be applied to IC package families where conventional wire bonding is replaced with copper plated vias and lines (traces).

United States Patent Application Publication Nos. 2018/0342453 A1, 2019/0115287 A1, 2020/0203264 A1, 2020/0321274 A1, 2021/0050226 A1, 2021/0050299 A1, 2021/0183748 A1, 2021/00305191 A1, 2021/0305203 A1 or 2023/0035470 A1 (all assigned to companies of the STMicroelectronics group and incorporated herein by reference) are exemplary of the possibility of applying LDS technology in manufacturing semiconductor devices.

For instance, LDS technology facilitates replacing wires, clips or ribbons with lines/vias created by laser beam processing of an LDS material followed by metallization (growing metal such as copper via a plating process, for instance).

Electrically conductive coupling can be provided in the LDS material (once consolidated, via thermosetting, for instance): as through mold vias (TMVs) that extend through an LDS encapsulation between a top (front) surface of the LDS encapsulation and electrically-conductive pads at the front or top surface of a chip or die and/or corresponding leads in a leadframe, and as electrically-conductive lines or traces that extend at the front or top surface of the LDS encapsulation and electrically couple through mold vias to provide a desired electrical connection (routing) pattern.

Electrical components (passive components such as resistors, for instance) may be possibly arranged along one or more of the lines or traces.

Providing such electrically conductive formations using LDS material thus essentially involves: structuring these formations in the LDS material at the desired locations (by laser drilling, for instance), and growing electrically conductive material (a metal such as copper, for instance) at the locations previously structured (activated).

For instance, LDS technology facilitates replacing wires, clips or ribbons with lines/vias created by laser beam processing of an LDS material followed by metallization (growing metal such as copper via a plating process, for instance).

Solutions as described herein facilitate using otherwise standard clips (for instance in bridging a gap between a die backside and a leadframe connected by a clip) by avoiding various drawbacks related to other solutions such as: clip material milling/extrusion (which may involve large material volumes to be removed, tight thickness and planarity tolerances, overall cost); clip tip bending (which is hardly applicable to packages including thick materials, with ensuing risk of cracks); or using substrates such as leadframes with dual lead levels or including different elements (which is expensive and needs further dedicate assembly steps).

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the die or chip to other electrical components or contacts.

Essentially, a leadframe comprises an array of electrically-conductive formations (or leads) that from an outline location extend inwardly in the direction of a semiconductor chip or die thus forming an array of electrically-conductive formations from a die pad configured to have at least one semiconductor chip or die attached thereon. This may be via conventional means such as a die attach adhesive (a die attach film or DAF, for instance).

As described herein, LDS processing facilitates realizing customized solutions to connect leadframes and die together with flat clips.

For instance, in solutions as described herein: a package with LDS interconnections between a die and a leadframe can be produced with connection to the clip made possible with the usage of an ABF layer between traces and clip, which can be “lasered” to connect the clip and the traces; LDS technology can be applied to provide customized Cu interconnections on top of a leadframe to connect traces to clips; and an LDS Cu layer can be used to connect a die pad and leads and traces to clips.

To summarize: solutions as described herein can provide a customized connection between a die and a leadframe with a layer thickness that can be “tuned” vie LDS process parameters set up; the related deposition process facilitates covering possible variability in the material stack for instance a die thickness change; and the possibility exists of using standard (flat) clips, exempt from bending or other types of sculpturing/shaping with clips suited to be used within the framework of a full LDS interconnection.

Solutions as described herein are be compatible with JEDEC standards.

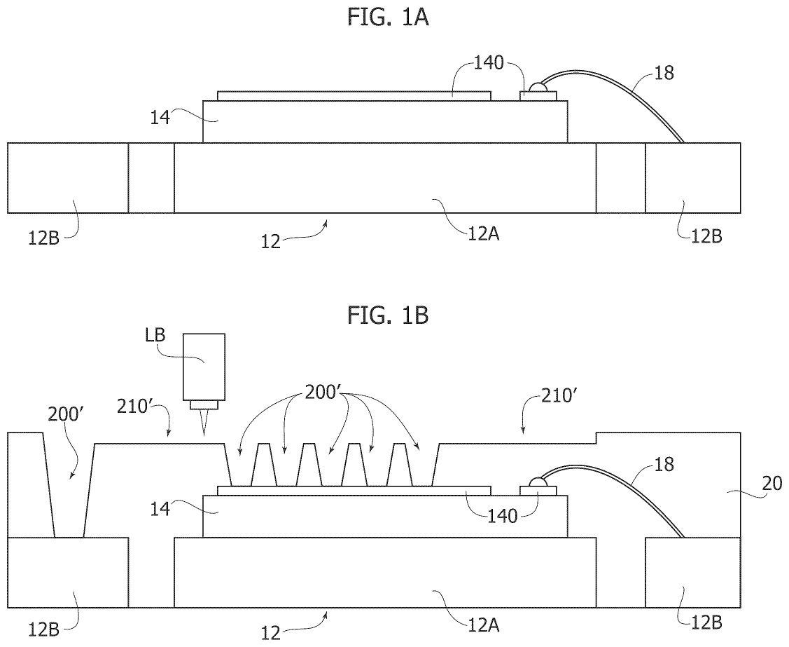

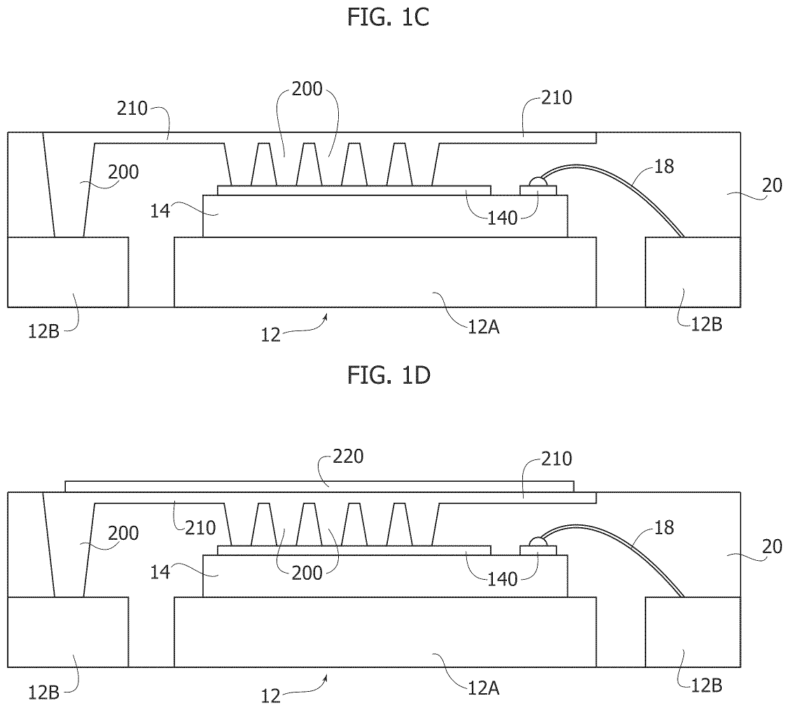

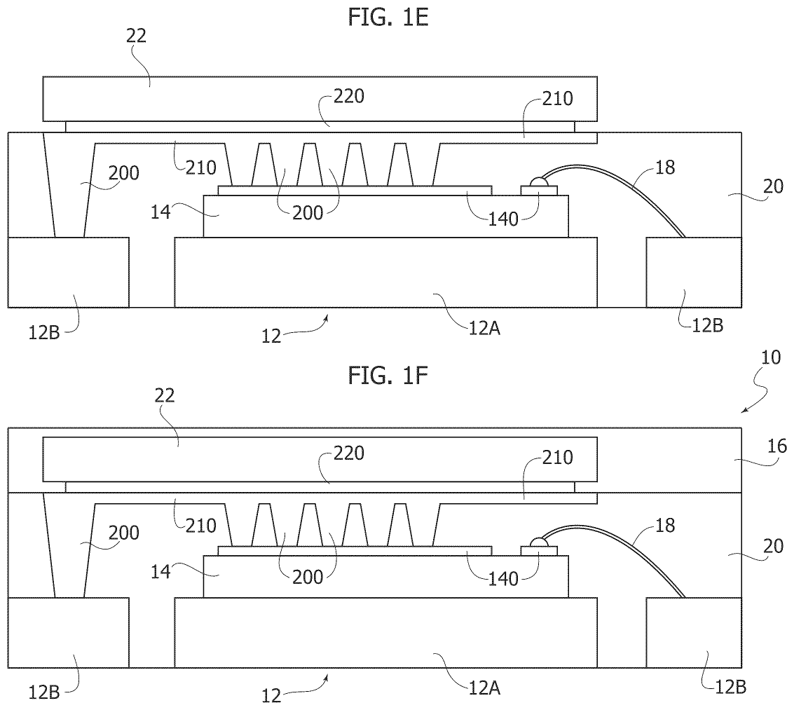

FIGS. 1A to 1F, FIGS. 2A to 2F, FIGS. 3A and 3B, and FIGS. 4A and 4B are all exemplary of possible (sequences of) steps in a process of manufacturing an IC semiconductor device.

It will be otherwise appreciated that the representations in these figures are merely exemplary insofar as: one or more steps illustrated can be omitted, performed in a different manner (with other tools or processes, for instance) and/or replaced by other steps; additional steps may be added; one or more steps can be carried out in a sequence different from the sequence illustrated; and one or more steps illustrated in connection with any of the sequences illustrated can be exchanged with other steps.

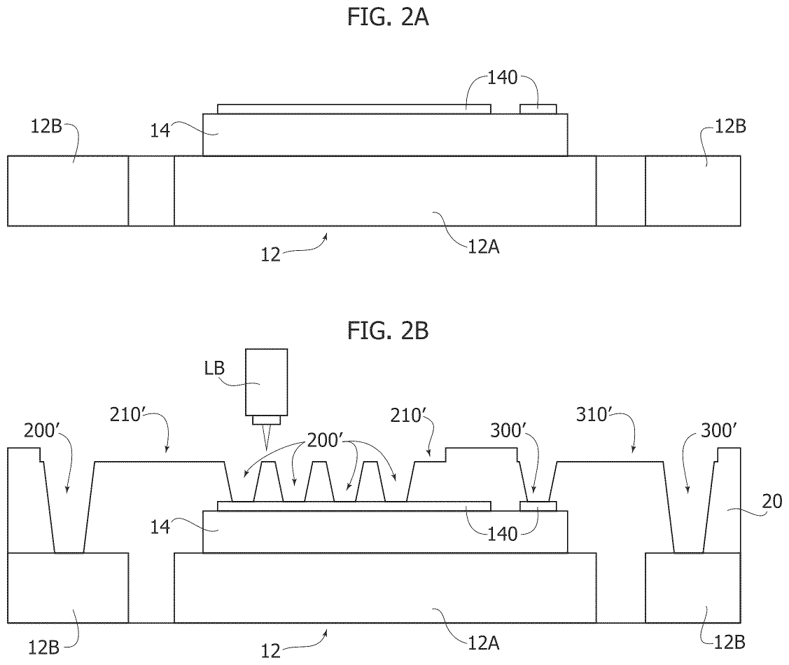

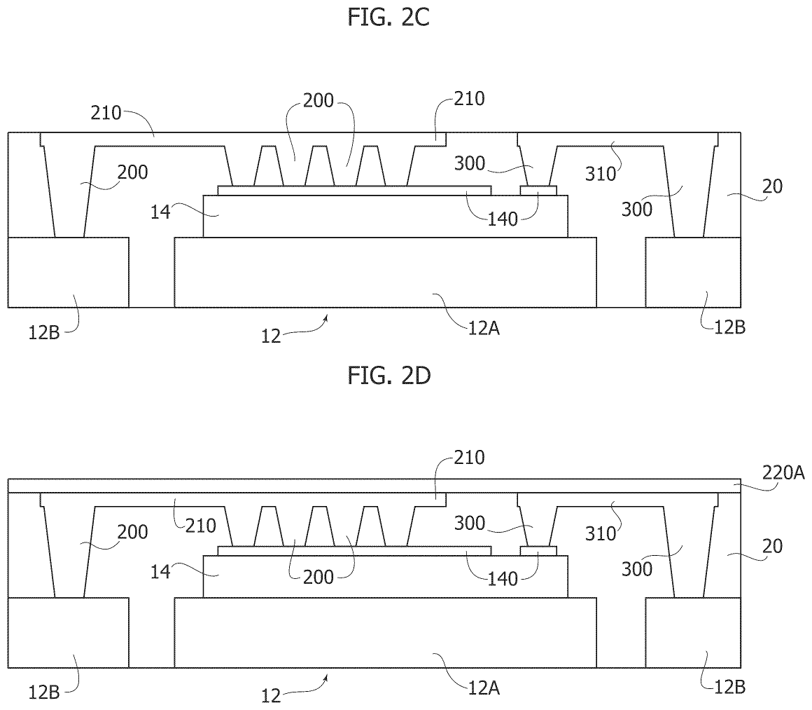

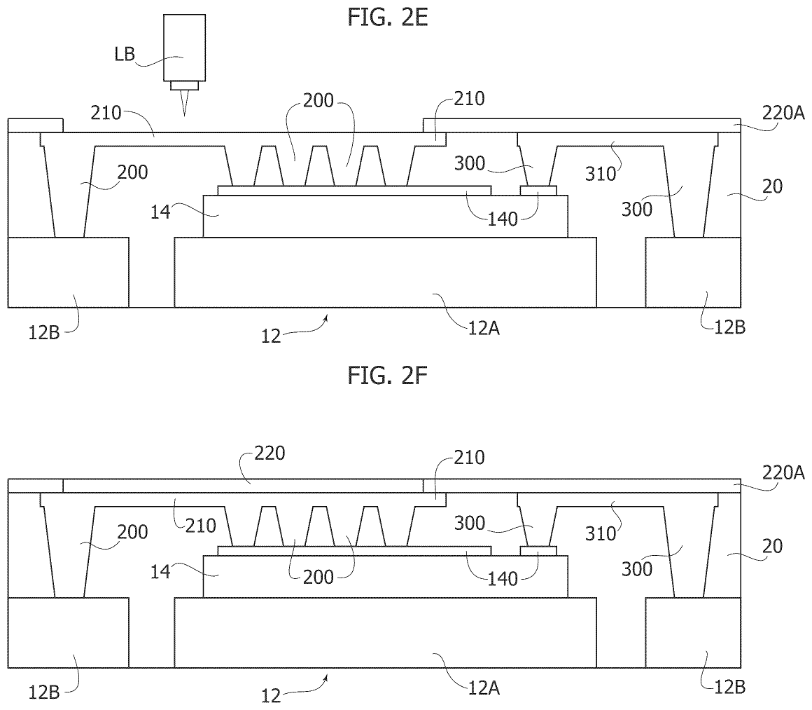

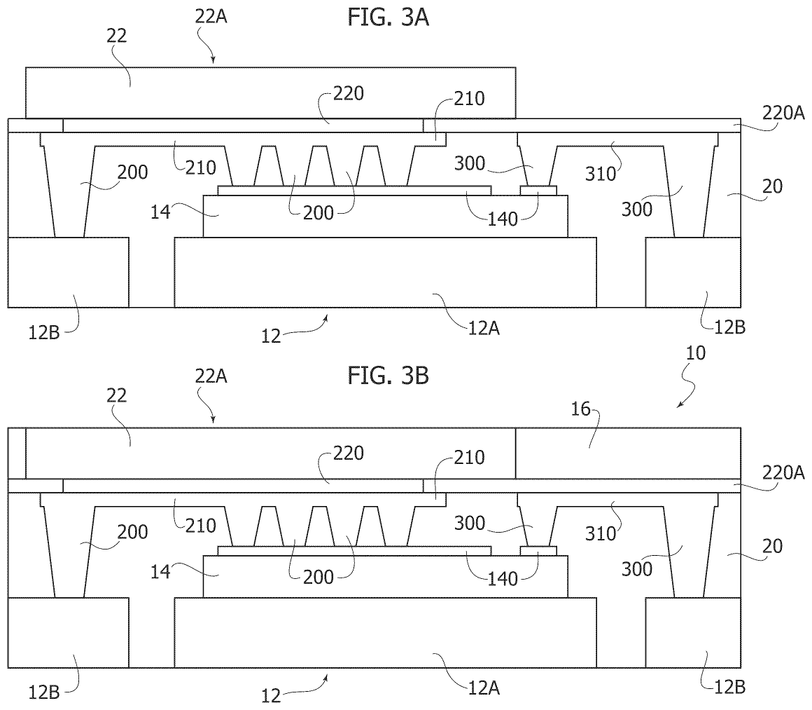

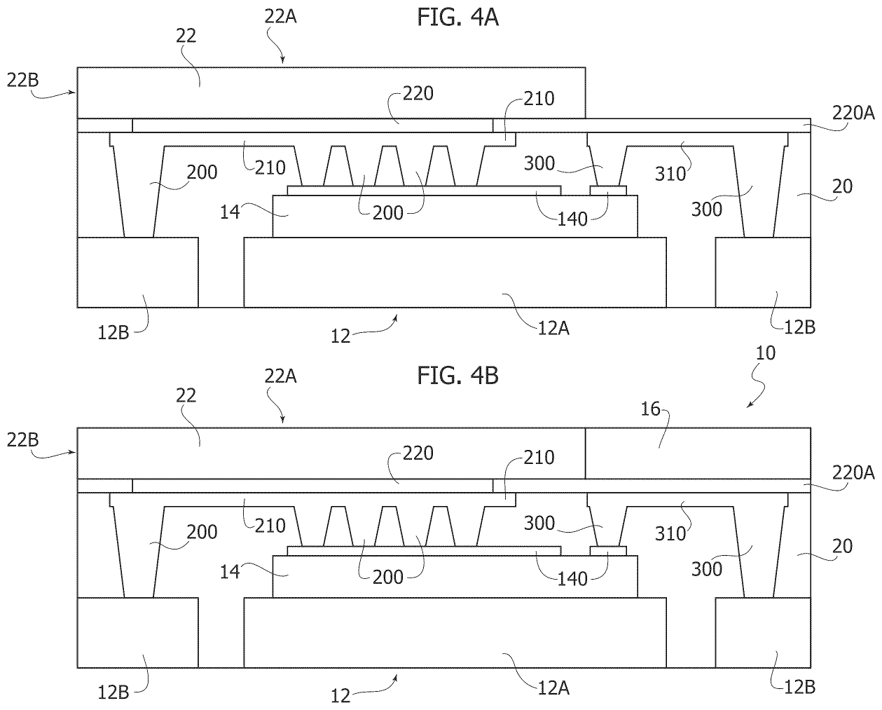

Merely by way of one possible example, the steps of FIGS. 3A and 3B and the steps of FIGS. 4A and 4B illustrate different ways of completing the sequence of steps exemplified in FIGS. 2A to 2F.

Solutions as described herein are applicable to (integrated circuit (IC)) semiconductor devices 10 with a plastic package that include (the references apply throughout the annexed figures): a substrate 12 (a leadframe, for instance) having one or more semiconductor chips or dice 14 arranged thereon at a die pad 12A via a die attach film, DAF, for instance (not visible as such); various possible arrangements of electrically conductive formations coupling the semiconductor chip(s) 14 to leads (outer pads) 12B in the substrate 12; and an insulating encapsulation (an epoxy resin, for instance) 16 molded on the assembly thus formed to complete the plastic body of the device 10.

Depending on the intended use and nature of the device 10, in various embodiments: the substrate 12 may be a leadframe, possibly of the pre-molded type; the substrate 12 may be of another type than a leadframe, for instance an electrically insulating layer having electrically conductive leads 12B provided therein.

Consequently: the die pad 12A may be electrically and/or thermally conductive; or the die pad 12A may be electrically and/or thermally non-conductive.

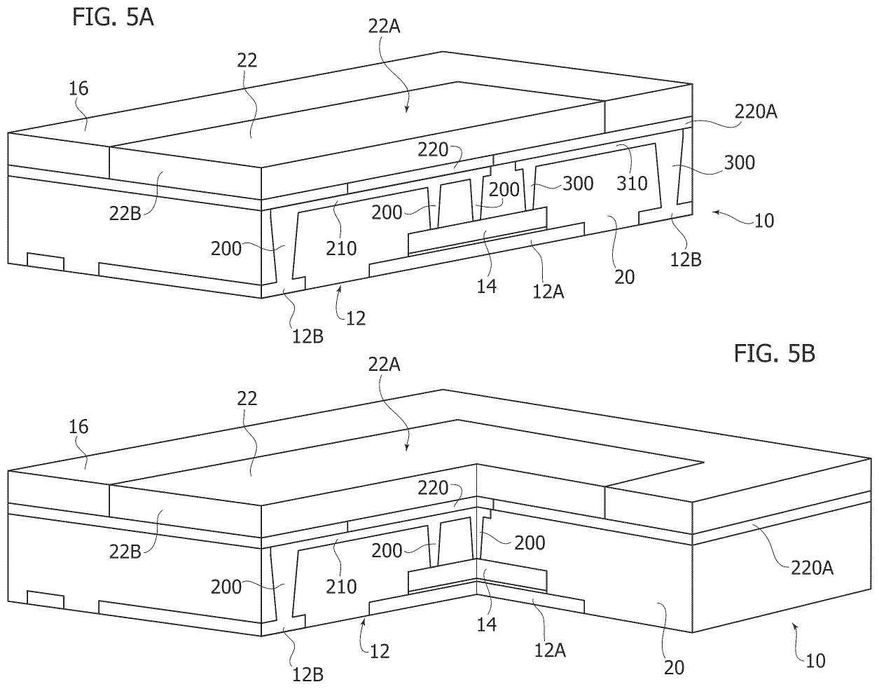

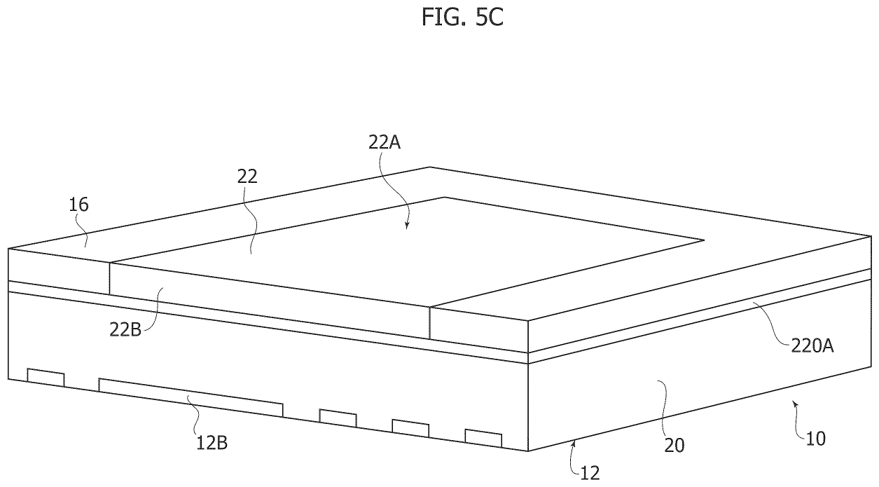

In addition to the leads 12B specifically referred to and labeled as such herein, the substrate 12 may include also other electrically conductive leads or traces that are not specifically discussed herein: some of these are visible, for instance, in FIGS. 5A to 5C.

Power semiconductor devices (for use in the automotive sector, for instance) may include a high-power section, and currents transferred from the high-power section to the output pads of the device can be significant.

Ribbons or clips can be used for that purpose in the place of wires with wires still used to provide electrical coupling to a low-power section (for instance, a controller) in the device. Clips are placed with a clip attach equipment, and a solder paste be used to connect the clip, with solder curing in an oven is applied to facilitate a solid connection.

FIGS. 1A to 1F are exemplary of a first possible sequence of steps in a process of manufacturing an (integrated circuit (IC)) semiconductor device 10.

As illustrated in FIG. 1A, a chip or die (as noted, these terms are used herein as synonymous) 14 is attached onto a die pad 12A of a substrate 12 and a wire bonding process (as known to those of skill in the art) can be used to provide electrical coupling of the die or chip 14 to one or more of the leads 12B via respective wires 18 extending between these leads 12B and respective die pads (or lands) 140 at the front (top) surface of the chip or die 14.

FIG. 1B is illustrative of a mass of LDS material 20 (of any known type to those of skill in the art) being molded onto the structure of FIG. 1A with vias 200′ (200) and traces 210′ (210) subsequently formed therein via laser beam energy LB applied as known in LDS processing.

As illustrated (by way of example) in FIG. 1B, vias 200′ (200) are formed in the LDS material 20: at those locations where die pads (or lands) 140 are present at the front (top) surface of the chip or die 14 other than the die pads or lands 140 to which the wire or wires 18 are bonded; and at locations of the substrate 12 where leads 12B are present (see for instance the lead 12B illustrated near the left-hand end of FIGS. 1A to 1F) that may be intended to be electrically coupled to selected ones of these “other” die pads (or lands) 140, namely die pads or lands 140 to which no wires 18 are bonded.

As illustrated (by way of example) in FIG. 1B, traces 210′ (210) are formed in the LDS material 20 to couple according to a desired routing pattern the proximal (here upper) ends of selected ones of the vias 200.

In response to the action of laser beam energy LB, the LDS material is “structured” (activated) and electrically conductive material (copper, for instance) can be plated at the locations 200′ and 210′ where laser beam energy LB has been applied.

As exemplified in FIG. 1C, plating (via electroless deposition and electrolytic deposition, as known to those of skill in the art) facilitates the formation of a desired electrically conductive pattern of vias 200 and traces 210 coupling the chip or die 14 to the leads 12B in addition to the wire bonding pattern of the wires 18.

It is noted that in FIG. 1B, reference numbers with apostrophes (200′, 210′) are used to indicate those locations of the LDS material 20 where laser beam energy LB is applied to structure (“write”) therein the desired pattern of vias 200 and traces 210 that is subsequently provided via LDS plating as illustrated in FIG. 1C.

FIG. 1D is exemplary of tin (or other conductive material) 220 applied via plating or screen printing at selected locations over the pattern of vias 200 and traces 210 provided via LDS plating.

Thereafter a planar (advantageously flat) clip 22 is applied onto the layer 220 as exemplified in FIG. 1E.

The layer 220 being electrically conductive facilitates electrical coupling—with the capability of conveying currents of a certain intensity, as desirable for high-power semiconductor devices—of the clip or clips (only one is shown for simplicity) to the leads 12B.

FIG. 1F is exemplary of the insulating encapsulation 16 (a non-LDS material such as epoxy resin, for instance) being molded on the assembly thus formed to complete the plastic body (package) of the device 10, with the encapsulation 16 covering the clip.

As discussed later, this is not however a mandatory option in so far as the encapsulation 16 can be applied in such a way to leave the clip at least partly exposed (uncovered).

While not immediately appreciated in FIGS. 1A to 1F (these are essentially cross-sectional views across the device 10), the device 10 may include: a low-power section (the chip or die 14, such as a controller, for instance) that is coupled through the wire bonding pattern 18 and some of the vias 200 and traces 210 to selected ones of the leads 12B to carry low-power signals, and a high-power section (not expressly visible) that is coupled to some other leads 12B via the clip or clips 22 with the capability of conveying currents as generated by a high-power section of the device 10.

It is noted that in solutions as illustrated in FIGS. 1A to 1F, one or more flat clips 22 can be mounted that extend over other die-to-lead connections such as the wires 18 and are electrically insulated (via the LDS material 20) from the clip or clips 22.

FIGS. 2A to 2F are exemplary of another possible sequence of steps in a process of manufacturing an IC semiconductor device to be completed as exemplified in FIGS. 3A and 3B or as exemplified in FIGS. 4A and 4B.

The sequence of steps of FIGS. 2A to 2F has a number of features in common with the steps of FIGS. 1A to 1E.

The sequence of steps of FIGS. 2A to 2F differ from the sequence of steps of FIGS. 1A to 1E primarily because, in the process of FIGS. 2A to 2F, the wires 18 of the wire bonding pattern illustrated on the right-hand side of FIGS. 1A to 1F are replaced by vias and traces produced via LDS processing like the vias and traces illustrated at the center and at the left-hand side of FIGS. 1A to 1F.

As illustrated in FIG. 2A, a chip or die 14 is again attached onto a die pad 12A of a substrate 12: however, in this case no wire bonding is used to provide electrical coupling of the die or chip 14 at the die pads (or lands) 140 at the front (top) surface of the chip or die 14.

FIG. 2B is illustrative of a mass of LDS material 20 (of any known type to those of skill in the art) being molded onto the structure of FIG. 2A with vias 200′ (200) plus 300′ (300) and traces 210′ (210) plus 310′ (300) subsequently formed therein via laser beam energy LB applied as known in LDS processing.

In the case of the steps of FIGS. 2A to 2F, vias 200′ (200) and 300′ (300) are formed in the LDS material 20 at all locations where die pads (or lands) 140 are present at the front (top) surface of the chip or die 14.

As noted, in the case of the steps of FIGS. 2A to 2F, no wire bonding is used and electrical coupling of the die or chip 14 to the leads 12B shown on the right-hand side FIGS. 2A to 2F is provided through vias 300 and traces 310 “structured” in the LDS material 20.

As illustrated (by way of example) in FIGS. 2B and 2C, traces 210′ (210) and 310′ (310) are formed in the LDS material 20 to couple according to desired routing patterns the proximal (here upper) ends of selected ones of the vias 200, 300.

Here again, in response to the action of laser beam energy LB, the LDS material is “structured” (activated) and electrically conductive material (copper, for instance) can be plated at the locations 200′, 210′, 300′, and 310′ where laser beam energy LB has been applied.

As exemplified in FIG. 2C, plating (via electroless deposition and electrolytic deposition, as known to those of skill in the art) facilitates the formation of a desired electrically conductive patterns of vias 200, 300 and traces 210, 310 coupling the chip or die 14 to the leads 12B.

Also in this case, in FIG. 2B, reference numbers with apostrophes (200′, 210′, 300′, 310′) are used to indicate the locations of the LDS material 20 where laser beam energy LB is applied to structure therein the desired pattern of vias 200, 300 and traces 210, 310 that is subsequently provided via LDS plating as illustrated in FIG. 2C.

FIG. 2D is exemplary of an insulating film (ABF, for instance) 220A laminated onto the structure of FIG. 2C.

As exemplified in FIG. 2E, the film 220A can be selectively removed according to a desired routing/redistribution pattern.

This may occur via laser beam energy LB. While the same reference symbol, namely LB, is used to designate a laser beam source as in FIG. 2B, the laser beam source of FIG. 2E may in fact be a laser beam source different from the laser beam source of FIG. 2B.

The vias opened in the film 220A can be filled with tin (or other conductive material) 220 as illustrated in FIG. 2F.

At this point, a planar (advantageous flat) clip 22 is applied onto the layer 220 with an insulating encapsulation 16 (a non-LDS material such as epoxy resin, for instance) molded on the assembly thus formed to complete the plastic body of the device 10. See, for example, FIGS. 1E and 1F.

The insulating encapsulation 16 can be molded on the assembly thus formed to complete the plastic body (package) of the device 10. This can be done essentially as depicted in FIG. 1F, namely with the encapsulation 16 covering the clip 22.

FIGS. 3A and 3B and FIGS. 4A and 4B are illustrative of the sequence of the steps of FIGS. 2A to 2F being completed in such a way to leave the clip 22 at least partly exposed (uncovered).

In both instances illustrated in FIGS. 3A and 3B and in FIGS. 4A and 4B, the encapsulation 16 is molded leaving an outer (here upper) surface or side 22A of the clip 22 exposed (uncovered), which facilitates heat dissipation via a front side of the clip 22.

FIGS. 3A and 3B, on the one hand, and FIGS. 4A and 4B, on the other hand, are otherwise exemplary of possible different options in molding the encapsulation 16.

In the case exemplified in FIGS. 3A and 3B, only the outer surface or side 22A of the clip 22 is left exposed.

In the case exemplified in FIGS. 4A and 4B, in addition to the outer surface or side 22A, also a lateral side 22B of the clip 22 is left exposed to further facilitate heat dissipation.

As already noted, one or more steps illustrated in connection with any of the sequences illustrated can be exchanged with other sequences.

As a first possible example: the steps of applying the clip 22 and molding thereon the encapsulation 16 leaving one or more of the sides 22A, 22B of the clip uncovered (exposed) as illustrated in FIGS. 3A and 3B and FIGS. 4A and 4B can be applied in the step of FIG. 1F; and the step of fully covering the clip 22 with the encapsulation 16 as illustrated in FIG. 1F can be applied as an alternative to the options illustrated in FIGS. 3A and 3B and FIGS. 4A and 4B.

As another possible example, an insulating film (ABF, for instance) 220A can be laminated onto the structure resulting from FIG. 1C and then selectively removed according to a desired routing/redistribution pattern (again, this may occur via laser beam energy) with tin (or other conductive material) 220 filled in the sculpturing formed therein after which a planar (advantageous flat) clip 22 is applied onto the layer 220.

Whatever the specific options and details of implementation, the layer 220 being electrically conductive facilitates electrical coupling—with the capability of conveying currents of a certain intensity, as desirable for high-power semiconductor devices—of the (clip or clips to the leads 12B. Only one clip 22 (an aluminum clip, for instance) is shown for simplicity.

Again, while not immediately appreciated in FIGS. 1A to 1F, FIGS. 2A to 2F, FIGS. 3A and 3B or in FIGS. 4A and 4B (for simplicity and clarity of explanation, these are essentially cross-sectional views across the device 10), the device 10 may include: the low-power section (the chip or die 14, such as a controller, for instance) that is coupled through the wire bonding pattern 18 and some of the vias 200, 300 and traces 210, 310 to selected ones of the leads 12B to carry low-power signals; and a high-power section (not expressly visible) that is coupled to some other leads 12B via the clip or clips 22 with the capability of conveying currents as generated by a high-power section of the device 10.

Solutions as illustrated herein facilitate providing during LDS (LDW, DCI) die-to-lead interconnection, forming a conductive (metal, for instance) layer 220 that is configured to receive a planar, flat clip 22 mounted thereon with vias (200, for instance) to connect the layer 220 to the die 14 and—at least—one lead 12B.

Solutions as illustrated herein may include laminating an insulating film 220A (ABF, for instance), forming vias therein (see FIG. 2E, for instance) and filling with solder paste.

In solutions as illustrated herein, one or more flat clips 22 can be mounted that extend over other die-to-lead connections (see the wires 18 in FIGS. 1A to 1F or the vias 300 and traces 310 in FIGS. 2A to 2F, FIGS. 3A and 3B and FIGS. 4A and 4B) that are electrically insulated from the clip or clips 22: this is via the LDS material 20, in the exemplary case of the wires 18 of FIGS. 1A to 1F, or via the film 220A (ABF, for instance), in the exemplary cases of the vias 300 and traces 310 in FIGS. 2A to 2F, FIGS. 3A and 3B and FIGS. 4A and 4B).

These advantageous features of solutions as discussed herein can be further appreciated in FIGS. 5A, 5B, and 5C.

FIG. 5A is a perspective view of an IC semiconductor device 10 partly sectioned along a “vertical” plane (namely a plane orthogonal to the general plane of the device 10) to highlight an internal structure essentially as illustrated in FIG. 4B (the same reference numbers apply in FIG. 4B and FIG. 5A).

FIG. 5B is a perspective view of the IC semiconductor device 10 of FIG. 5A partly sectioned along two mutually orthogonal planes sharing a vertical axis (namely an axis perpendicular to the general plane of the device 10) approximately at the center of the chip or die 14. Here again, reference numbers already appearing in FIG. 4B and FIG. 5A are used in FIG. 5B.

FIG. 5B highlights a flat clip 22 mounted in such a way to extend over the die-to-lead connections provided by the vias 300 and traces 310 that are electrically insulated from the clip 22 via the film 220A (ABF, for instance).

FIG. 5C is a perspective view of the IC semiconductor device 10 of FIG. 5A and FIG. 5B no longer sectioned so that the full extension of the flat clip 22 can be appreciated.

As used herein “flat”, applied to the clip or clips 22 designates a planar clip that is advantageously exempt from any bending or sculpturing giving rise to undesirably complex shapes and/or increased cost.

Without prejudice to the underlying principles, the details and embodiments may vary, even significantly, with respect to what has been described in the foregoing, by way of example only, without departing from the extent of protection.

The claims are an integral part of the technical teaching on the embodiments as provided herein.

The extent of protection is determined by the annexed claims.

1. A method, comprising:
arranging at least one semiconductor chip on a substrate having electrically conductive leads;
molding laser direct structuring (LDS) encapsulation material onto the semiconductor chip arranged onto the substrate;
applying LDS processing to the LDS encapsulation material to provide a pattern of electrically conductive formations coupled to selected ones of the electrically conductive leads;
providing electrically conductive material onto the pattern of electrically conductive formations; and
arranging at least one planar electrically conductive clip onto the electrically conductive material, wherein the at least one planar electrically conductive clip is electrically coupled via the electrically conductive material to one or more leads of said selected ones of the electrically conductive leads.

2. The method of claim 1, wherein the at least one at least one planar electrically conductive clip comprises a flat clip.

3. The method of claim 1, comprising molding further encapsulation material onto the at least one planar electrically conductive clip.

4. The method of claim 3, wherein the at least one planar electrically conductive clip comprises front and lateral surfaces facing away from the electrically conductive material and wherein molding further encapsulation material comprises molding further encapsulation material onto the at least one planar electrically conductive clip leaving said front surface uncovered by the further encapsulation material.

5. The method of claim 4, further comprising leaving said lateral surface uncovered by the further encapsulation material.

6. The method of claim 1, wherein the substrate comprises a further set of electrically conductive leads and the method comprises:
electrically coupling the at least one semiconductor chip arranged onto the substrate to selected leads in said further set of electrically conductive leads; and
electrically insulating said further set of electrically conductive leads from the at least one planar electrically conductive clip.

7. The method of claim 1, wherein the substrate comprises a further set of electrically conductive leads and the method comprises:
electrically coupling the at least one semiconductor chip to selected leads in said further set of electrically conductive leads via a wire bonding pattern; and
molding LDS encapsulation material onto the semiconductor chip, wherein the LDS encapsulation material electrically insulates the further set of electrically conductive leads and the wire bonding pattern from the at least one planar electrically conductive clip.

8. The method of claim 1, wherein providing electrically conductive material onto the pattern of electrically conductive formations comprises:
applying an electrically insulating layer onto the pattern of electrically conductive formations;
opening at least one via through the electrically insulating layer to the pattern of electrically conductive formations; and
filling said electrically conductive material into the at least one via.

9. The method of claim 1, wherein the substrate comprises a further set of electrically conductive leads and the method comprises:
electrically coupling the at least one semiconductor chip arranged onto the substrate to selected leads in said further set of electrically conductive leads;
electrically insulating said further set of electrically conductive leads from the at least one planar electrically conductive clip;
applying LDS processing to the LDS encapsulation material molded onto the semiconductor chip arranged onto the substrate to provide a further pattern of electrically conductive formations coupling the at least one semiconductor chip arranged onto the substrate to selected leads in said further set of electrically conductive leads; and
applying said electrically insulating layer onto the further pattern of electrically conductive formations, wherein the electrically insulating layer insulates said further set of electrically conductive leads and said further pattern of electrically conductive formations from the at least one planar electrically conductive clip arranged onto said electrically conductive material.

10. A device, comprising:
at least one semiconductor chip arranged on a substrate having electrically conductive leads;
a pattern of electrically conductive formations coupled to selected electrically conductive leads, wherein the pattern of electrically conductive formations are laser direct structured formations provided in LDS encapsulation material molded onto the semiconductor chip;
electrically conductive material on the pattern of electrically conductive formations; and
at least one planar electrically conductive clip arranged onto the electrically conductive material, wherein the at least one planar electrically conductive clip is electrically coupled via the electrically conductive material to at one or more leads of said selected electrically conductive leads.

11. The device of claim 10, wherein the at least one planar electrically conductive clip comprises a flat clip.

12. The device of claim 10, comprising further encapsulation material molded onto the at least one planar electrically conductive clip arranged onto the electrically conductive material.

13. The device of claim 12, wherein the at least one planar electrically conductive clip comprises front and lateral surfaces facing away from the electrically conductive material with the further encapsulation material molded onto the at least one planar electrically conductive clip arranged onto the electrically conductive material leaving said front surface uncovered.

14. The device of claim 13, wherein said lateral surface is also left uncovered by the further encapsulation material.

15. The device of claim 10, wherein the substrate comprises a further set of electrically conductive leads wherein the at least one semiconductor chip arranged onto the substrate is electrically coupled to selected leads in said further set of electrically conductive leads, said further set of electrically conductive leads being electrically insulated from the at least one planar electrically conductive clip arranged onto said electrically conductive material.

16. The device of claim 15:
wherein the at least one semiconductor chip arranged onto the substrate is electrically coupled to selected leads in said further set of electrically conductive leads via a wire bonding pattern, wherein said LDS encapsulation material molded onto the semiconductor chip arranged onto the substrate electrically insulates the further set of electrically conductive leads and the wire bonding pattern from the at least one planar electrically conductive clip arranged onto said electrically conductive material.

17. The device of claim 15:
wherein the at least one semiconductor chip arranged onto the substrate is electrically coupled to selected leads in said further set of electrically conductive leads via a further pattern of electrically conductive formations, the further pattern of electrically conductive formations being laser direct structured in said LDS encapsulation material molded onto the semiconductor chip arranged onto the substrate, and wherein the electrically conductive material comprises electrically conductive material filling the at least via opened through an electrically insulating layer applied onto the pattern of electrically conductive formations, wherein the electrically insulating layer insulates said further set of electrically conductive leads and said further pattern of electrically conductive formations from the at least one planar electrically conductive clip arranged onto said electrically conductive material.
